(19) United States
(12) Patent Application Publication
(10) Pub. No.: US 2005/0157469 A1
(43) Pub. Date: Jul. 21, 2005

(54) Cooling arrangement for a printed circuit board with a heat-dissipating electronic element

(76) Inventor: Gracjan Gorak, Zielona Gora (PL)

Correspondence Address: WILLIAM COLLARD;COLLARD & ROE, P.C., 1077 NORTHERN BOULEVARD, ROSLYN, NY, 11576, US

(21) Appl. No.: 11/016,339

(22) Filed: Dec. 17, 2004

(30) Foreign Application Priority Data
Dec. 19, 2003 (PL) 364153

(51) Int. Cl. H05K 7/20

(52) U.S. Cl. 361/719; 361/720; 361/707; 361/704

(57) ABSTRACT

A cooling arrangement for a printed circuit board with a heat-dissipating electronic element comprises a radiating layer (108, 208, 308) on the top side of the PCB (100, 200, 300) and a covering (103, 203, 303) for thermally connecting the top side of the heat-dissipating electronic element (101, 201, 301) and the radiating layer (108, 208, 308), wherein the heat-dissipating electronic element is mounted on the bottom side of the PCB and the PCB is mounted horizontally. The covering can be made of a good heat conductor, e.g. copper, while the bottom side of the covering can be protected by a heat-insulating layer (105, 205, 305). The covering can have plain (104A, 204A) or notched (104B, 204B) arms.

### CROSS-REFERENCE TO RELATED APPLICATIONS

This application claims priority to Polish Application No. P-364153, filed Dec. 19, 2003, the contents of which are incorporated herein by reference.

### BACKGROUND OF THE INVENTION

1. Field of the Invention

The present invention relates to a cooling arrangement for a printed circuit board with a heat-dissipating electronic element.

2. Brief Description of the Background of the Invention Including Prior Art

Electronic elements are often cooled by radiators, mounted directly on the elements. In order to improve the cooling efficiency, radiators often have their base bigger than the surface of the element being cooled. However, such radiators cannot be used if the cooled element is surrounded by higher elements.

Methods of heat dissipation are under continuous improvement. The improvements apply to methods of assembly of the radiator, to shapes of radiator or to other ways of heat dissipation. Such a high number of various ideas suggests that the there is a constant need for improvement of the present methods of electronic elements cooling.

The U.S. Pat. No. 5,870,285 “Assembly mounting techniques for heat sink in electronic packaging” presents an assembly support mount for a radiator that includes at least two flexible retention posts, with ends to engage a radiator frictionally, to support it relative to the cooled electronic device. Although the assembly support allows easy mounting of the radiator, it does not increase the cooling efficiency.

The U.S. Pat. No. 5,710,459 “Integrated circuit package provided with multiple heat-conducting paths for enhancing heat dissipation and wrapping around cap for improving integrity and reliability” presents a printed circuit board with an integrated circuit chip thereon, wherein said chip includes a ball grid array having a plurality of conductive metal balls electrically and thermally connected to said integrated circuit chip. The PCB comprises a plurality of thermal vias penetrating the main board and filled with thermally conductive materials, which are in thermal contact with the conductive metal balls for dissipating heat generated from said IC to the opposite side of the PCB. Moreover, the chip has a radiator mounted thereon. However, the heat from the radiator is dissipated to the opposite side than the side from which the heat from the metal balls is dissipated.

The U.S. Pat. No. 5,920,458 “Enhanced cooling of a heat dissipating circuit element” presents an arrangement for cooling a heat dissipating circuit element mounted to a first side of a printed circuit board, where a heat dissipation member is mounted to the other side of the PCB and a thermally conductive post secured to the heat dissipation member extends through an aperture through the PCB and into thermal contact with the circuit element. Therefore, the heat is dissipated only from the bottom part of the element.

The U.S. Pat. No. 6,188,578 “Integrated circuit package with multiple dissipation paths” presents a heat spreader attached to a PCB to cover the die mounted on the PCB and contact with the backside of the die. The heat from the die can be conducted both upward to the outer environment and downward to the PCB through the heat spreader. However, heat is dissipated to the internal layer of the PCB, which does not ensure effective heat dissipation.

### SUMMARY OF THE INVENTION

Purposes of the Invention

It is an object of the present invention to provide a cooling arrangement for a printed circuit board with a heat-dissipating electronic element. The presented arrangement, taking advantage of the heat exchange principle, provides a very efficient way for electronic elements cooling. The direction of heat flow is forced from the electronic element, situated on the bottom side of the PCB, to the radiating layer, situated on its top side, which provides a better cooling efficiency than the methods known before.

These and other objects and advantages of the present invention will become apparent from the detailed description, which follows.

### BRIEF DESCRIPTION OF THE INVENTION

A cooling arrangement for a printed circuit board with a heat-dissipating electronic element, according to the present invention, comprises a radiating layer on the top side of the PCB and a covering for thermally connecting the top side of the heat-dissipating electronic element and the radiating layer, wherein the heat-dissipating electronic element is mounted on the bottom side of the PCB and the PCB is mounted horizontally.

The covering can be made of a good heat conductor, e.g. copper, while the bottom side of the covering can be protected by a heat-insulating layer.

A thermally conductive paste can be used as a thermal connection between the covering and the heat-dissipating electronic element.

The arms of the covering can be placed in the holes of the PCB, while their bent terminals can be connected with the radiating layer by means of a thermally conductive paste.

The surface of the radiating layer can have decrements, surrounding the places of mounting other heat dissipating elements. The decrements can be placed around signal paths.

The covering can have plain or notched arms.

The covering can be fastened to the bottom side of the PCB, where vias, connected with the radiating layer, are located.

A radiator can be additionally attached to the radiating layer.

The heat-dissipating electronic elements can be additionally connected with the radiating layer through a via in the PCB.

The novel features, which are considered as characteristic for the invention are set forth in the appended claims. The invention itself, however, both as to its construction and its method of operation, together with additional objects and advantages thereof, will be best understood from the following description of specific embodiments when read in connection with the accompanying drawings.

### BRIEF DESCRIPTION OF THE DRAWINGS

In the accompanying drawings one of the possible embodiments of the present invention is shown, where

FIG. 1 shows a cross section of the PCB with the covering, fastened in the holes in the PCB;

FIG. 2 and FIG. 3 show a top and a bottom view of the PCB from FIG. 1, with the covering with plain arms;

FIG. 4 and FIG. 5 show a top and a bottom view of the PCB from FIG. 1, with the covering with notched arms;

FIG. 6 shows a cross section of the PCB with the covering attached to its bottom side;

FIG. 7 and FIG. 8 illustrate the bottom and top view of the PCB from FIG. 6, with the covering with plain arms;

FIG. 9 illustrates a section of the PCB with the covering, attached to its bottom side, and the radiator, fastened to the radiating layer, located at its top side, while the heat-dissipating electronic element has an additional thermal connection with the radiating layer.

Throughout the drawings, the same reference numerals indicate similar or corresponding features or functions. The drawings are not necessarily to scale; instead the emphasis is placed upon illustrating the principles of the invention.

### DESCRIPTION OF INVENTION AND PREFERRED EMBODIMENT

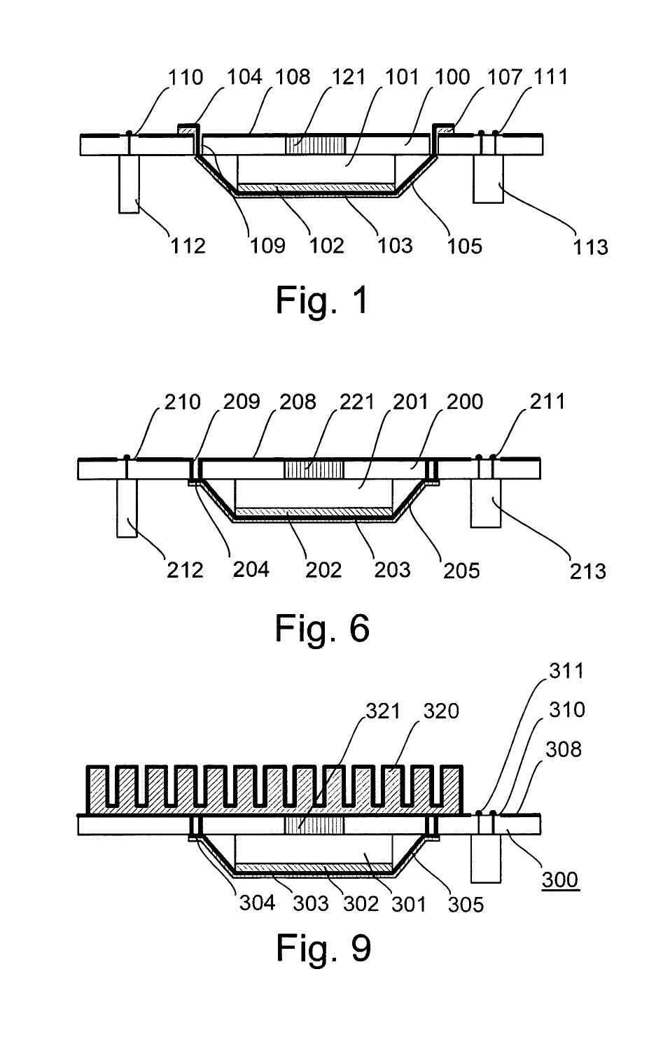

FIG. 1 presents a cross section of the PCB 100, with a heat dissipating electronic element 101, for example an integrated circuit chip, mounted at its bottom side. A covering 103 is assembled on the top side of the electronic element 101, with its arms extending through holes 109 in the PCB, and its terminals 104 bent. The covering is made of a good thermal conductor, for example copper. The part of the covering 103 at the bottom side of the PCB is covered with a thermal insulator 105, reducing the heat dissipation at its surface.

The top side of the PCB 100 is covered with a copper layer 108 for dissipating heat through radiation. Preferably, if there are no elements or signal paths on the top side of the PCB 100, the radiating layer can cover its entire surface.

The covering 103 can be initially, before assembling, profiled in such a way that its assembly involves only the activity of bending the terminals of the arms 104 placed in the holes 109 in the PCB 100.

The covering 103 is thermally connected with the element 101 by means of thermally conductive paste 102. After bending, the terminals of the arms 104 are thermally connected with the radiating layer 108 of the PCB 100 by means of thermally conductive paste 107.

Other elements, 112 and 113, can be mounted at the bottom side of the PCB 100 and attached to the top side of the PCB by means of pins 111. There is a decrement 110 of the radiating layer surrounding these pins, which ensures that there is no electric or thermal contact of the radiating layer 108 with other elements of the PCB 100.

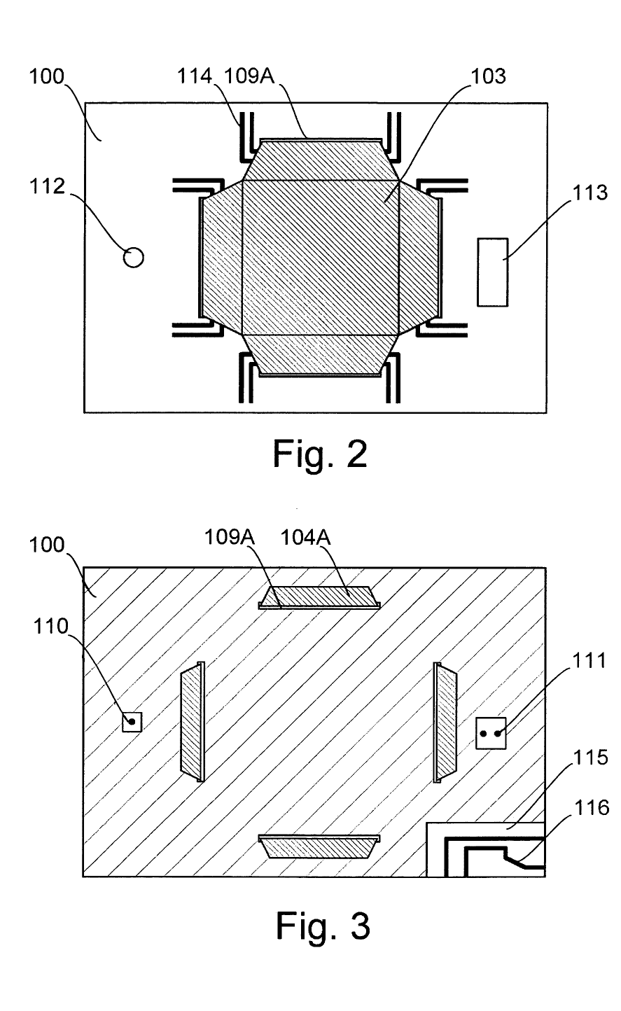

FIG. 2 shows a bottom view of the PCB 100 with a covering with plain arms. The covering has four narrowing arms 104A, which extend through the holes 109A in the PCB. On the top side of the PCB there are also signal paths 114 leading to the electronic element 101.

FIG. 3 presents a top view of the PCB 100 shown in FIG. 2. There are decrements 110 in the radiating layer 108, surrounding the pins of elements 112 and 113. The radiating layer 108 has preferably a large surface. However, if signal paths 116 have to be conducted on the top side, a decrement 115 in the radiating layer is formed around those paths.

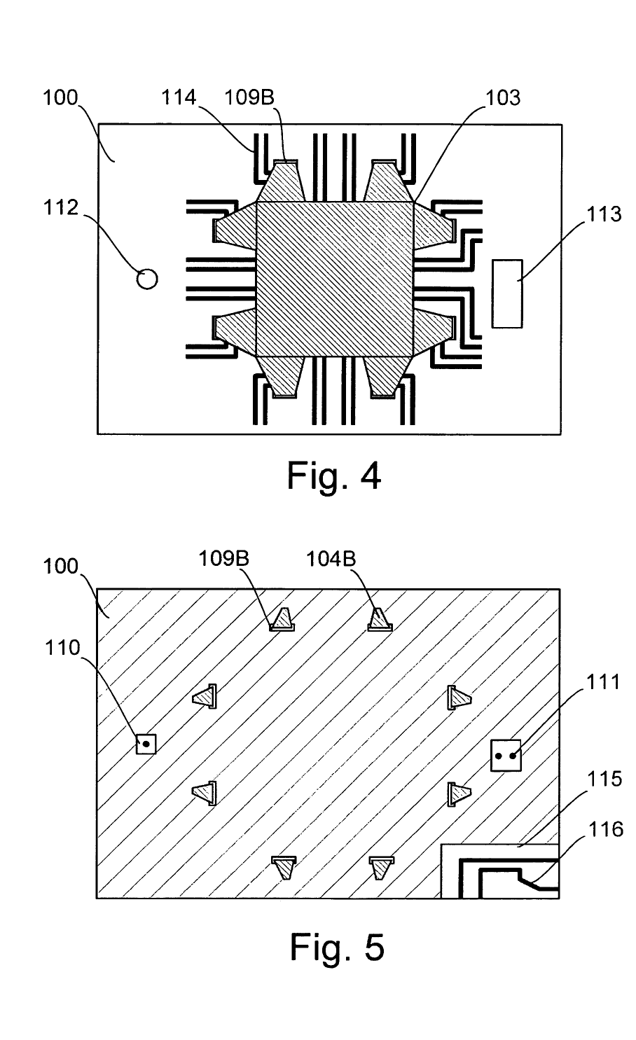

FIG. 4 and FIG. 5 present respectively the bottom and the top view of the PCB 100 with a covering with notched arms 104B. The covering 103 has two arms on each side. The holes 109B are narrower than the holes of the covering with plain arms 104A. The spacing between arms allows conducting additional signal paths therein.

FIG. 6 illustrates a cross section of the PCB 200, with a heat-dissipating electronic element 201 mounted at its bottom side, with a covering 203, which is fastened to the bottom side of the PCB, for example by means of soldering or gluing. The PCB has vias 209 with metal-covered side surfaces, which conduct heat to the radiating layer 208 on the top side of the PCB. This solution has two additional advantages in comparison to the solution presented in FIG. 1. First, the assembly of the covering 203 is easier, there is no necessity to bend arms, because the covering 203 is already formed in the way it is to be fastened on the PCB. Second, it is possible to cover the entire external surface of this covering with a thermal insulator 205.

The vias 209 can be additionally filled with a thermally conductive material, for example paste.

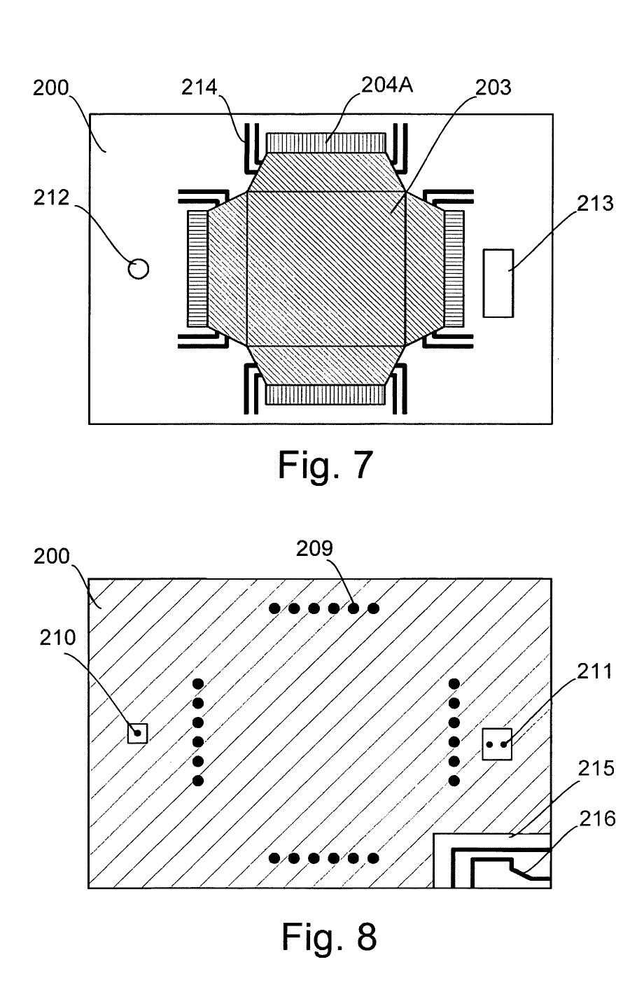

FIG. 7 and FIG. 8 present respectively the bottom and the top views of the PCB 200 shown in FIG. 6, with the covering with plain arms 204A. As shown in the top view, each arm of the covering 203 can be connected with many vias 209.

The elements 202, 210, 211, 212, 213, 214, 215, 216 shown in FIGS. 6, 7 and 8 are equivalent to the respective elements: 102, 110, 111, 112, 113, 114, 115, 116 from FIGS. 1, 2 and 3.

The covering 203, which is fastened to the bottom side of the PCB 200 can also have notched arms 204B, which are not shown in the drawing, similar to the arms of the covering 103 presented in FIGS. 4 and 5. The use of notched arms 104B and 204B allows easier leading of signal paths than in case of plain arms 104A and 204A.

FIG. 9 presents a cross section of the PCB 300, with the covering 303 fastened to the bottom side of the PCB, similarly as shown in FIG. 6. There is a finned radiator 320 additionally fastened to the radiating layer 308. The use of the radiator can improve the efficiency of heat dissipation, especially when there is a fan, fastened above the top side of the PCB, which causes air flow. The assembly of the radiator 320, especially with a large surface of the base is very convenient because of the flat assembly surface.

The heat-dissipating electronic element 301 can be additionally connected with the radiating layer 308 through a via 321, which dissipates heat from the base of the element. The via 321 can be filled with a thermally conductive material, e.g. copper. Alternatively, a series of small vias can be applied as well, with their walls covered with copper. The vias 321 are connected with the bottom layer of the electronic element 301, preferably to its thermally conductive terminals, in order to improve the efficiency of cooling.

The additional vias 121 and 221 for dissipating heat from electronic elements 101 and 201 can be also applied to the embodiments presented in FIG. 1 and FIG. 6.

The PCB may have several heat-dissipating electronic elements assembled thereon using the described techniques, each of them connected with the radiating layer through a covering. The radiating layer can be homogeneous, which allows equal spread of heat to all the elements and over the entire top surface of the PCB. Alternatively, the radiating layer can be divided into several distinct areas, so that each electronic element is connected to a separate radiating layer. The cooling efficiency is best if the PCB is placed horizontally. However, if placed at a slope or vertically, the cooling efficiency will be lower, but still efficient.

The foregoing description of the preferred embodiments of the invention has been presented for purposes of illustration and description. They are not intended to be exhaustive of to limit the invention to the precise form disclosed, and obviously many modifications and variations are possible in light of the above teachings. Such modifications and variations that are apparent to a person skilled in the art are intended to be included within the scope of this invention as defined by the accompanying claims.

1. A cooling arrangement for a printed circuit board with a heat-dissipating electronic element, comprising
a radiating layer on the top side of the PCB; and
a covering for thermally connecting the top side of the heat-dissipating electronic element and the radiating layer;
wherein the heat-dissipating electronic element is mounted on the bottom side of the PCB and the PCB is mounted horizontally.

2. The cooling arrangement according to claim 1, wherein the covering is made of a good heat conductor, preferably copper, and the external part of the covering is protected by a heat-insulating layer.

3. The cooling arrangement according to claim 1, wherein the thermal connection between the covering and the electronic element is provided by means of a thermally conductive paste.

4. The cooling arrangement according to claim 1, wherein the arms of the covering are placed in the holes of the PCB, and the bent terminals of the arms are connected with the radiating layer by means of a thermally conductive paste.

5. The cooling arrangement according to claim 1, wherein the radiating layer of the PCB has decrements surrounding the place of fastening of other electronic elements.

6. The cooling arrangement according to claim 1, wherein the radiating layer of the PCB has decrements surrounding the signal paths.

7. The cooling arrangement according to claim 1, wherein the covering has plain arms.

8. The cooling arrangement according to claim 1, wherein the covering has notched arms.

9. The cooling arrangement according to claim 1, wherein the covering is fastened to the bottom side of the PCB and thermally connected with the radiating layer through vias.

10. The cooling arrangement according to claim 1, wherein a radiator is additionally fastened to the radiating layer of the PCB.

11. The cooling arrangement according to claim 1, wherein the electronic element is additionally connected with the radiating layer through a via in the PCB placed between the bottom of the electronic element and the radiating layer.
